(19) United States
(12) Patent Application Publication
(10) Pub. No.: US 2026/0313788 A1
(43) Pub. Date: Oct. 8, 2026

(54) METHOD FOR MANUFACTURING CONDUCTIVE TRACKS AND TRANSPARENT LAMINATED PANE

(71) Applicant: ams-OSRAM International GmbH, Regensburg (DE)

(72) Inventor: Thomas Schwarz, Regensburg (DE)

(21) Appl. No.: 19/108,378

(22) PCT Filed: Sep. 4, 2023
(86) PCT No.: PCT/EP2023/074202

§ 371 Date: Mar. 3, 2025

(30) Foreign Application Priority Data
Sep. 7, 2022 (DE) 10 2022 122 745.6

(51) Int. Cl. H05K 1/02; H05K 3/20

(52) U.S. Cl. CPC H05K 1/0274; H05K 3/20; H05K 2201/10121

(57) ABSTRACT

In an embodiment a transparent laminated pane includes a transparent carrier, a conductive grid structure arranged on the carrier including a plurality of first conductive tracks in a first direction and a plurality of second conductive tracks in a second direction crossing the first conductive tracks, wherein the conductive grid structure is divided into at least three spatially separated regions and at least a first one of the three regions has a subregion which has a subset of the plurality of first conductive tracks and no conductive tracks extending in the second direction, an insulating layer arranged at least partially on the subset of the plurality of first conductive tracks in the subregion, and a number of conductors extending in the second direction on the insulating layer, which contact conductive tracks from one of a second region or a third region.

### CROSS-REFERENCE TO RELATED APPLICATIONS

This patent application is a national phase filing under section 371 of PCT/EP 2023/074202, filed Sep. 4, 2023, which claims the priority of German patent application no. 10 2022 122 745.6, filed Sep. 7, 2022, each of which is incorporated herein by reference in its entirety.

### TECHNICAL FIELD

The present invention relates to methods for manufacturing a plurality of conductive tracks on a transparent target substrate, in particular a pane. The invention also relates to a transparent pane arrangement, in particular a vehicle pane.

### BACKGROUND

Transparent displays are increasingly in demand in vehicles, but also in other regions. The term “transparent display” refers to a display surface that is capable of displaying various information to an observer by means of light, but is also transparent so that a user can see through the surface both when the display is switched on and when it is switched off. In this way, dynamic information can be displayed alongside static information. The displays can be scaled so that they can be used in vehicle windows such as cars, airplanes, spaceships, buses, etc., but also in window panes for buildings. Less complex transparent displays with a few illuminated symbols, e.g. on doors etc., are also possible

Transparent displays and symbols typically have a transparency of around 70%. This means that the transparency, for example in a car side window, is compared to a conventional window (transmission of laminated safety glass ~90%) significantly reduced.

One reason for this is the use of conductive tracks made of metals or transparent oxides on glass or transparent plastics (PET, PEN, PI) for such transparent substrates. In some conventional applications, which have proven to be useful from a circuitry point of view, multilayer cross-matrix circuits are applied to a transparent substrate and connected to components so that passive and active displays can be realized.

In addition, some transparent displays require several layers in order to form bridges, for example, or to achieve a higher component or circuit density in some regions of the display.

Especially in such regions, conventional arrangements reduce transparency or make the additional levels visible to the user.

### SUMMARY

Embodiments provide a low visibility for the viewer of conductive tracks in transparent displays, while achieving a high component density.

If the component density is to be increased in transparent displays, several layers are placed on top of each other in more complex transparent pane composite systems, which in turn are separated from each other by a transparent insulating layer. Due to the grid-like lattice structure used, however, additional layers become visible to the user. The same applies when bridging structures or regions that belong to a different circuit. In addition, the grid-like lattice structure leads to increased resistance of the cables, especially when forming bridges.

The inventor therefore proposes a different approach, which on the one hand requires less material and on the other hand reduces the disadvantages described above, in particular reduced transparency at flatter viewing angles.

In some aspects, a transparent laminated pane is proposed for this purpose, which comprises a transparent carrier or a transparent substrate with a conductive grid structure arranged thereon. The grid structure has a plurality of first conductive tracks in a first direction and a plurality of second conductive tracks in a second direction, which cross the first conductive tracks. The conductive grid structure is further divided into at least three spatially separated regions, and at least a first one of the three regions comprises a subregion. This subregion is now designed differently from the rest of the grid structure and comprises a subset of the plurality of conductive tracks extending in the first direction. Furthermore, the subregion does not have any conductive tracks extending in the second direction. In other words, the subregion does not comprise any intersecting conductive tracks.

According to the proposed principle, an insulating layer is now provided, which is arranged at least partially on the subset of the plurality of conductive tracks extending in the first direction in the subregion. A number of conductive tracks extending in the second direction are now provided on the insulating layer, which extend into an adjacent region and contact a region there from one of the second and third regions.

In this way, a bridge structure of essentially parallel conductive tracks is created, which is placed on a subregion whose conductive tracks run perpendicular to it. The resulting structure in plan view thus corresponds to the remaining grid structure on the transparent substrate. This results in an essentially identical visual impression. At the same time, the length of the conductive tracks remains short.

In some aspects, the contact regions between the plurality of second-direction conductors and traces of one of the second and third regions are spaced from the subregion by at least one trace extending in the first direction. In other words, the bridge structure formed by the plurality of conductive tracks extends across the subregion to connect two regions of the grid structure on the substrate separated by the subregion.

In another embodiment, contact regions between the number of conductors and conductive tracks extending in the second direction from one of the second and third regions are arranged at crossing points of first and second conductive tracks in this region.

Some aspects deal with the number of conductors extending in the second direction. In some embodiments, these can comprise a cross structure arranged in the contact region, comprising a plurality of the number of conductive tracks extending in the second direction and sections arranged perpendicularly thereto. Alternatively, a grid contact structure can be arranged in the contact region, whereby in particular its grid length corresponds to a grid length of the grid structure. It is also conceivable to specify circular, elliptical, star-shaped or square contact points whose positions correspond to crossing points of first and second conductive tracks of the respective region.

In other aspects, contact regions may also be implemented on the grid structure of the transparent support. Accordingly, in some aspects, circular, elliptical, star-shaped or square contact points are provided as part of the crossing points between first and second conductive tracks, wherein optionally end regions of the number of conductive conductors extending in the second direction extend beyond the contact points

Similarly, in some aspects, a plurality of contact points may be provided that are located along the number of conductors extending in the second direction at intersection points between first and second conductive tracks, wherein optionally end regions of the number of conductors extending in the second direction extend beyond the contact points. Finally, contact points can be provided which are arranged as part of the crossing points between first and second conductive tracks, with end regions of the number of conductors extending in the second direction optionally extending beyond the contact points.

In some other aspects, the first and second conductive tracks on the transparent support are arranged substantially perpendicular to each other, at an angle of 40° or at an angle of 60° to each other. At least some of the conductive tracks are conductively coupled to each other in at least some of the crossing points. The number of conductors extending in the second direction electrically connects the two other regions. In particular, a bridge structure is realized in this way, which bridges the subregion and connects two otherwise electrically isolated regions of the grid structure.

Some aspects deal with the insulating layer. In some aspects, the insulating layer may extend at least partially into the regions adjacent to the subregion, in particular into the other regions. It is possible that the insulating layer is formed as a film, wherein generally the insulating layer has dimensions that are larger than the corresponding dimensions of the subregion.

Thus, in some aspects, the insulating layer extends to first and/or second conductive tracks adjacent to the subregion, in particular first and/or second conductive tracks arranged in the second and/or third region. Alternatively, the first and/or second conductive tracks adjacent to the subregion, which are arranged in the second and/or third region, may be substantially free of material of the insulating layer. In some aspects, the subregion comprises a width that is substantially bounded by the second and/or third region.

The insulating layer can be formed as a continuous surface of the transparent material. However, it is also possible to arrange the insulating layer in strips, with a width that is only slightly greater than the width of the conductive tracks arranged on it. The position should be aligned along the vertically extending conductive tracks in the regions to be coupled. In another embodiment,, the insulating layer comprises circular elements that are arranged at the intersection points between the horizontally extending conductive tracks of the subregion on the carrier and the second conductive tracks of the bridge structure.

In some further aspects, two of the at least three regions are also coupled to each other via a component, in particular an optoelectronic component. In some other aspects, the plurality of conductors extending in the second direction on the insulating layer is laterally offset from the plurality of second conductors connected to the plurality of conductors on the support.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a top view of a possible intermediate product of an exemplary laminated pane according to some aspects of the proposed principle;

FIG. 2 shows a top view of a section of an exemplary laminated pane according to some aspects of the proposed principle;

FIG. 3 shows a top view of a section of a further exemplary laminated pane according to some aspects of the proposed principle;

FIG. 4 shows a top view of a section of a further exemplary laminated pane according to some aspects of the proposed principle;

FIG. 5 shows a top view of a section of a further exemplary laminated pane according to some aspects of the proposed principle;

FIG. 6 shows a top view of a section of a further exemplary laminated pane according to some aspects of the proposed principle;

FIGS. 7A to 7F are illustrations of possible conductive tracks that can be used in a bridge structure according to the proposed principle;

FIGS. 8A to 8D show exemplary sections of possible contact regions of grid structures on the carrier to illustrate further aspects according to the proposed principle; and

FIGS. 9A and 9B show sectional views through a section of an exemplary laminated pane according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

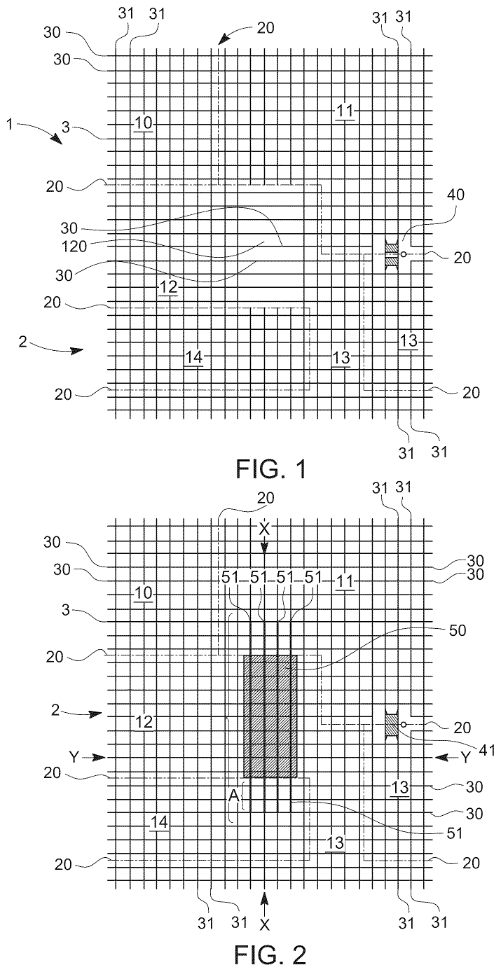

FIG. 1 shows an embodiment of a laminated pane in plan view before the placement of a bridge structure according to some aspects of the proposed principle.

The laminated pane 1 as shown in FIG. 1 comprises a carrier substrate 2 to which a grid structure 3 is applied. The grid structure 3 in turn has a large number of intersecting conductive tracks 30 and 31. In detail, the conductive tracks 30 are arranged parallel to each other and intersect the conductive tracks 31, which are also arranged parallel, at an angle that is essentially perpendicular to them. For the sake of simplicity, the conductive tracks 30 are referred to as horizontal conductive tracks and the conductive tracks 31 as vertical conductive tracks for the purpose of this application. However, it is known to the skilled person to also provide other crossing angles for the various conductive tracks in order to realize the proposed principle and the desired grid structure 3. Furthermore, in this embodiment example, the distances between the individual conductive tracks 30 or 31 are the same in each case, so that the checkerboard-like pattern shown in FIG. 1 is produced. In this context, it is also possible to select the individual spacings differently in order to achieve the desired realization depending on the requirements of the application. The individual conductive tracks 30 and 31 cross each other at different points and are electrically conductive to each other. This results in a conductive connection at every point of the grid structure 3.

The grid structure 3 shown in FIG. 1 is divided into different regions 10, 11, 12, 13 and 14 by separating sections 20. The individual separating sections 20 intersect the conductive tracks 30 or 31, so that there is no longer a conductive connection through continuous conductive tracks between the individual regions 10 to 14. In other words, at this point in the manufacturing process, the individual regions 10, 11, 12, 13 and 14 of the grid structure 3 on the carrier substrate 2 are electrically insulated from each other. Separation by the separating sections can be achieved, for example, by laser ablation of the individual conductive tracks, but also by mechanical separation such as grinding, sawing, etching away the corresponding conductive track structures or the like. In this embodiment example, the width of the separating sections essentially corresponds to a grid spacing of the grid structure formed from the conductive tracks 30 and 31. Depending on the embodiment, however, the separating sections 20 can also be larger or smaller, as long as insulation between the individual regions is ensured by the separating sections 20.

Between the regions 11 and 13 there is a contact region 40 for a component, which in a later state of the laminated pane 1 is occupied by an optoelectronic component. In addition, the region 12 comprises a subregion 120 which extends between two separating sections 20. Specifically, this is the separating section which separates the region 20 from the region 12 and the separating section which electrically isolates the region 14 from the region 12.

According to the proposed principle, the subregion 120 is designed in such a way that it comprises only first conductive tracks 30, i.e. horizontal conductive tracks; the vertical conductive tracks 31 also present in the remaining region 12 are deliberately omitted in the subregion 120, so that a grid structure 3 is not formed here as in the remaining regions, but only a large number of horizontal strip-shaped conductive tracks. As already visible in the top view, this results in a slightly greater transparency and a slightly different visual impression. It should also be mentioned at this point that the embodiment shown in FIG. 1 can also be rotated so that the subregion 120 in such a case only has vertically extending conductive tracks but no horizontal conductive tracks. In other words, according to the proposed principle of this application, the subregion 120 is designed in such a way that conductive tracks run in it without crossing, i.e. there are no crossing conductive tracks.

This subregion is now covered with a thin insulating layer 50 according to the proposed principle. The insulating layer 50 is also transparent and comprises, for example, a transparent plastic, silicon dioxide, or a transparent silicone or epoxy. It is applied as a thin layer in a printing, dispensing or jetting process. In some aspects, a very thin film can also be used, which either sticks itself or is provided with an adhesive layer. The thickness of the insulation layer is a few um.

In the present embodiment, the insulation material extends from the one upper separating section 20 between the regions 11 and 12 across the subregion 120 to the lower separating section 20 between the regions 12 and 14. In this way, it forms a rectangle which covers the entire width of the subregion 120. In this embodiment, the insulation layer is thus limited to the subregion 120. However, it may also be provided that the insulation layer partially extends over the separating sections into the regions 11 and 14, i.e. is slightly longer or wider than the separating section. This can be particularly useful when using a film, since in this case a slight offset can be compensated for when applying the film.

A large number of conductors 51 are now arranged on the insulation layer 50, which run essentially parallel to the conductive tracks 31 on the carrier substrate 2. Together with the insulation layer, these conductors 51 form a bridge structure and are electrically coupled to the conductive tracks 31 and 30 in region 11. Similarly, the conductors 51 are also electrically connected to the conductive tracks 31 and 30 of region 14 in region 14 via track A. The bridge structure designed in this way electrically couples the region 11 to the region 14. According to the proposed principle, the structure of the bridge is designed in such a way that the conductors 51 run on the insulation layer 50 in only one direction without crossing. In particular, the shape and orientation of the conductive tracks 52 follow the vertical conductive tracks 31 present in other subregions and regions.

Accordingly, the grid-like structure shown in plan view in FIG. 2 also results in the subregion 120. In contrast to conventional solutions and bridges, in which the grid structure 3 present in the region 12 is simply bridged with additional conductors, in the present embodiment example according to the proposed principle there is only one group of vertically extending conductors, namely the conductors 51. To put it simply, there are only two types of conductive tracks in the subregion 120, which cross over each other in plan view and not, as in conventional solutions, further conductive tracks or conductive track planes, which result from the fact that the actual grid structure of the subregion to be bridged is not adapted as proposed.

As a result, even at different viewing angles, no different impression is created for the subregion 120 compared to the impression in the other regions 10 to 14. In particular, even at flatter viewing angles, i.e. viewing angles from the side, a user does not get the impression that the subregion 120 with its bridge structure additionally shades, as is the case with conventional solutions. Likewise, due to the relatively short distance, i.e. the direct connection of the conductors 51, the resistance is reduced compared to other solutions in which a grid-like structure is realized.

In addition, the contact region 40 is fitted with an optoelectronic component 41, which electrically couples the region 13 with the region 11.

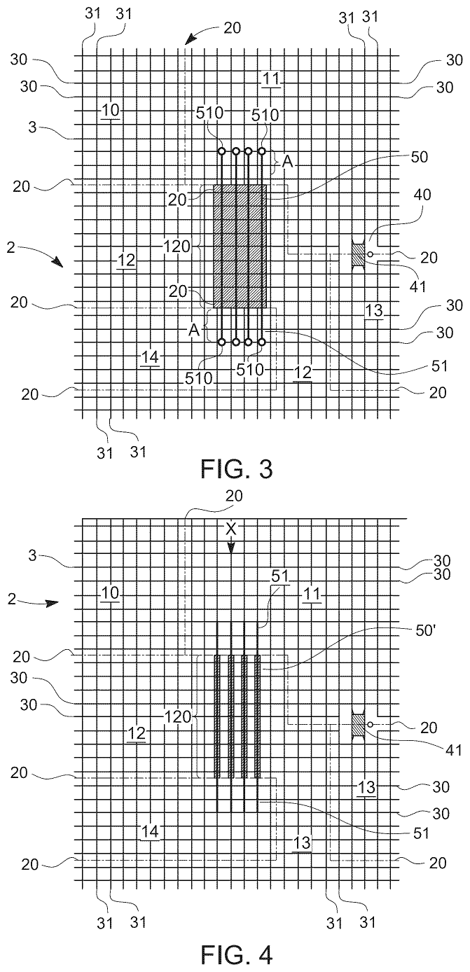

FIG. 3 shows a slightly modified version of such a bridge. Here, the vertically extending conductors 51 are arranged slightly laterally offset from the original conductive tracks 31 in the regions 11 and 14. End regions 510 are provided on the conductors 51. These are designed as circular contact surfaces and thus enable sufficiently good electrical contact with the corresponding vertical or horizontal conductive tracks in regions 11 and 14, even with a slight offset. Depending on the viewing angle, the vertical conductive tracks in region 11 and in the region of the parallel tracks 51 as well as in region 14 appear slightly thicker, which could generally reduce transparency. However, due to the small size of the sections of the conductors 51 in regions 11 and 14, this effect is negligible, especially in the case of longer bridge sections.

In subregion 120, on the other hand, this effect of the slight offset is not visible for region 12 due to the lack of vertical conductive tracks in this subregion, so that the overall effect of a possibly reduced transmission due to the slight offset is limited. In addition, in this case the sections of the conductors 51 only extend over two grid lengths, which should be quite small compared to the entire length of the bridge.

This embodiment shown in FIG. 3 is particularly advantageous compared to conventional solutions because, as shown, a slight lateral offset in the implementation of such a bridge connection is not of major significance in the solution. This also makes it possible to realize different deposition or application processes for the embodiment with greater tolerances than would be the case with conventional solutions.

FIG. 4 shows a further embodiment of the proposed principle, in which the bridge and in particular the insulating layer between the vertically extending conductors 51 and the horizontally extending conductors 30 of the subregion are designed differently.

In this embodiment example, in contrast to the previous embodiments, the insulation layer is not applied to the entire surface of the subregion 120. Rather, the insulation layer touches the individual cables 51 in the form of a strip or a sheathing, so that strip-shaped insulation layers 50′ are provided in the subregion 120. The design can be realized in various ways. On the one hand, it is possible to use a jetting or other dispensing process to arrange thin strips separated from each other along the conductive tracks to be laid later on the subregion 120 and in this way cover the individual horizontal conductive tracks 30. The material of the conductors 51 is then applied to these strips and connected to the conductors in the subregion 11 or 14.

Alternatively, it is also possible to produce the conductors 51 with an insulating material 50′, namely before the conductors 51 are applied to the subregion and the corresponding connection points in the region 11 and 14. In this embodiment, the conductors 51 thus resemble conventional untreated wires, as is possible in particular with larger cross-sections on conductive tracks. In both cases, the transmission is further improved because the insulation material only extends around a thin region around the vertically extending conductors 51, but not in the otherwise free region between the individual vertically extending conductive tracks. Nevertheless, sufficient insulation is achieved between the conductors 51 and the horizontally extending conductive tracks 30 of the subregion 120.

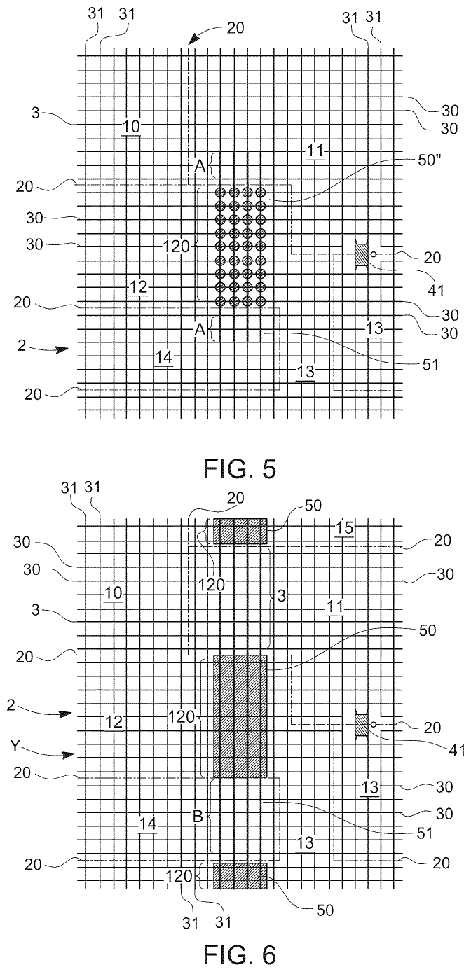

FIG. 5 shows a further embodiment in which the amount of insulating material used is further reduced. In this embodiment, drop-shaped dots 50″ of the insulating material are applied to the later crossing points on the horizontally extending conductive tracks 30 in the subregion 120. These thus extend over subregions of the horizontally extending conductive tracks 30. The vertical conductors 51 are then applied starting from the regions 11 or 14 over the insulation points along the subregion 120. This results in a series of points 50″ of insulating material, which are arranged at a respective crossing point between the conductors 51 and 30 in the subregion 120 and thus insulate them electrically from one another. In the sections A in the regions 11 and 14, as in the previous embodiment examples, the conductors 51 are connected to the vertical regions of the conductive tracks 31 and 30 in order to ensure sufficiently good electrical contact.

The proposed principle of using conductive tracks as bridging structures in subregions in which other conductive tracks are removed can also be transferred to applications in which the region to be bridged can comprise several subregions of different regions. FIG. 6 shows a corresponding embodiment example in which the conductors 51 span several subregions 120.

In the present embodiment example, two spatially separated subregions 120 are provided in the region 12, between which a section of the region 14 is arranged. The subregions 120 are each formed with horizontally extending conductive tracks 30, but no corresponding vertically extending conductive tracks 31. An insulating layer 50 is arranged over each of the subregions 21, to which vertically extending conductor sections 51 are applied. These also extend along the sections B of the regions 11 and 14 and make electrical contact with them there. In addition, a further region 15 is provided, which is also formed with a bridge, i.e. with an insulating material 50 in its subregion 120.

In this way, the conductors 51 can contact sections B in different regions 11 and 14 and extend as bridge structures across other regions such as 12 and 15 along the respective subregions. In this way, a connection across several bridge elements and bridge sections is possible between different spatially separated regions without the transparency of these regions being significantly impaired.

There are several ways of contacting the individual conductors 51 of the bridge element on the regions to be contacted.

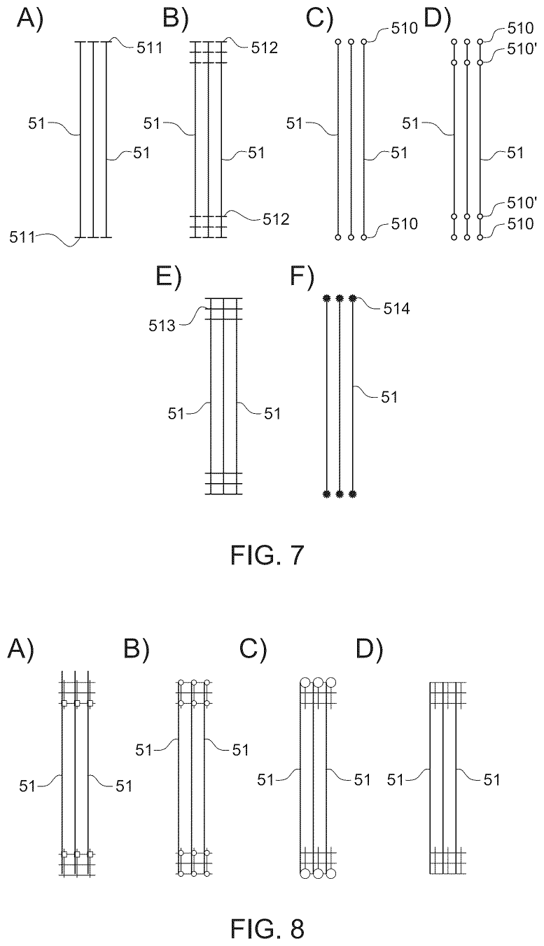

FIGS. 7A to 7F show various embodiments of this. In FIG. 7A, the end regions 511 of the respective conductors 51 are manufactured with a T-piece, i.e. a section perpendicular to the conductors 51. In an implementation, the perpendicular sections thus also run perpendicular to the respective vertical conductive tracks 31 or parallel to the horizontally extending conductive tracks 30.

In partial FIG. 7B, several such sections 512 are provided to improve contacting. Accordingly, a cross structure is thus partially formed. The additional sections 512 are spaced apart from one another at a distance equal to the grid length of the underlying grid structure on the substrate. The overall length of the conductors 51 of the bridge structure is selected such that the sections 512 extending perpendicularly thereto come to lie on or in the immediate vicinity of the crossing points on the regions to be contacted. This results in better contacting and therefore lower contact resistance.

In a further embodiment shown in FIG. 5C, the end regions are designed as circular surfaces 510. This embodiment corresponds to the embodiment of FIG. 3, whereby the region of the end regions 510 can be selected to be of different sizes so that they ensure sufficiently good contacting when the conductors 51 are applied to the insulating sections or the regions to be contacted.

A further improvement is shown in FIG. 7D, in which the contact surfaces 510 are arranged several times and thus form contact surfaces 510′. The distance between the individual contact surfaces 510 and 510′ along the conductors 51 again corresponds to a grid length or a multiple thereof, so that the corresponding surfaces preferably come to lie on the crossing points of the conductive tracks 30 and 31.

FIG. 7E shows a further embodiment in which the end regions of the conductors 51 are provided with grid structures 513. These grid structures correspond in size and design, for example, to the grid structure of the conductive tracks 30 and 31 on the underlying substrate. This results in particularly simple manufacture, since such bridge structures with the elements 51 and 513 can already be manufactured on a finished substrate and then transferred to the insulation material and the neighbouring regions to be contacted. Sub-figure 7F again shows an alternative embodiment to sub-figure 7C, in which the end regions are formed here by a star-shaped structure 514, which increases the possible contact surface to the regions to be contacted and the conductive tracks.

In addition to a corresponding structuring of the end regions of the conductors 51, it is also possible to adapt the sections for contacting in the respective regions to be contacted on the substrate and thus provide a structuring of the horizontally or vertically extending conductive tracks 30 and 31.

FIGS. 8A to 8D show corresponding embodiments, whereby the conductors 51 of the bridge structure are arranged laterally slightly offset to the corresponding sections on the regions of the grid structure 3 to be contacted on the transparent carrier 2 for better illustration. Partial FIG. 8D corresponds to the normal configuration without further measures and is therefore particularly easy to produce. In sub-figure 8A, some crossing points of the vertical or horizontal conductive tracks are provided with star structures in the contact sections of the regions. This results in a larger contact surface between the conductive tracks 30 and 31 and the conductors 51 of the bridge structure. In sub-figure 8B, round contact surfaces are provided at several crossing points, so that better contact is achieved here due to the larger contact surface. A similar advantage is also achieved in partial FIG. 8C, where the contact surface is also greatly enlarged. The main differences between sub-figures 8B and 8C are that the enlarged contact surfaces in sub-figure 8C are only located at one crossing point of the vertical conductive tracks, whereas the contact surfaces in sub-figure 8B are located at several conductive tracks extending parallel to each other.

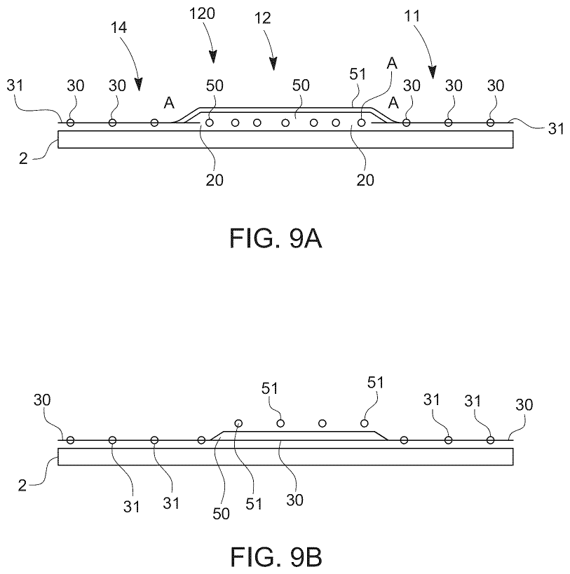

FIG. 9A now a cross-section X-X along a horizontal conductive track through the regions 14, 12 and 11 of FIG. 2, in which a bridge structure is provided for bridging the subregion 120. The cross-section includes the carrier 2, on which a large number of conductive tracks 30 are provided. These extend out of the sectional plane and are shown as circular conductive tracks for the sake of simplicity. The conductive tracks 31, which are interrupted by the separating sections 20, run along the drawing plane or parallel to it. The separating sections 20 thus divide the grid structure into the regions 14, 12 and 11. In the section shown through the subregion 120, the insulation material is now arranged over the individual conductors 30 within the subregion 120. Further conductors 51 are applied to the insulating material, which contact the conductive tracks 30 and the conductive tracks 31 in sections A of the subregions 14 and 11 respectively, thus creating an electrical connection between the region 14 and the region 11.

FIG. 9B shows a cross-sectional view of the same arrangement rotated by 90°. Now the horizontal conductors 30 run along and parallel to the drawing plane, while the vertical conductors 31 of the individual regions protrude from the drawing plane. In this cross-section, the conductors 51 on the insulating material 50 are led out of the drawing plane and cross over with the conductors 30 extending perpendicular to it in region 12, whereby they are electrically separated from each other by the insulating layer 51. In the top view, the user still only sees the cross structure, which is also visible outside the region 12 or 11 through the conductive tracks 30 and 31.

With the method presented here, a cost-effective generation of conductive tracks with a small width in the range of less than 10 μm and an associated insulation as an electrical bridge structure is realized. The idea is to provide, in the region of this bridge connection on the bridge plane, only conductive tracks extending in one direction, which intersect with the underlying conductive tracks on the substrate plane, in particular perpendicularly. The conductive tracks extending parallel to the bridge plane are removed from the substrate plane, so that only a simple structure is visible in plan view, which essentially corresponds to the grid structure 3 on the transparent carrier 2.

In this way, greater transparency is achieved, particularly with a lateral offset of the bridge structure or flat viewing angles and a thicker insulating layer. At the same time, the resistance of the bridge structure can be reduced as the conductor length is now continuous and no longer jagged. A lower electrical contact resistance is also possible by thickening the conductive tracks. Accordingly, grid structures and associated bridges can be produced with a lower adjustment accuracy and therefore lower associated costs, without having to accept losses in transparency or electrical properties. In addition, existing dispensing processes or jetting processes can be used efficiently.

1-15. (canceled)

16. A transparent laminated pane comprising:
a transparent carrier;
a conductive grid structure arranged on the carrier comprising a plurality of first conductive tracks in a first direction and a plurality of second conductive tracks in a second direction crossing the first conductive tracks,
wherein the conductive grid structure is divided into at least three spatially separated regions and at least a first one of the three regions comprises a subregion which comprises a subset of the plurality of first conductive tracks and no conductive tracks extending in the second direction;
an insulating layer arranged at least partially on the subset of the plurality of first conductive tracks in the subregion; and
a number of conductors extending in the second direction on the insulating layer, which contact conductive tracks from one of a second region or a third region.

17. The transparent laminated pane according to claim 16,
wherein contact regions, between the number of conductors extending in the second direction and conductive tracks from one of the second and third region are spaced apart from the subregion by at least one conductive track extending in the first direction, and/or
wherein contact regions, between the number of conductors extending in the second direction and conductive tracks from one of the second region or the third region are arranged at crossing points of first and second conductive tracks in this region.

18. The transparent laminated pane according to claim 16, wherein the number of conductors extending in the second direction comprises:
a cross structure arranged in a contact region and comprising a plurality of conductors extending in the second direction and sections arranged perpendicularly thereto, or
a grid contact structure arranged in the contact region, wherein in particular a grid length of which corresponds to a grid length of the grid structure, or
circular, elliptical, star-shaped or square contact points, whose positions correspond to crossing points of first and second conductive tracks of the respective region.

19. The transparent laminated pane according to claim 16, wherein, in a contact region,
circular, elliptical, star-shaped or square contact points are provided as part of the crossing points between first and second conductive tracks, wherein optionally end regions of the number of conductors extending in the second direction extend beyond the contact points, and/or
a plurality of contact points is provided along the number of conductors extending in the second direction at crossing points between first and second conductive tracks, wherein optionally end regions of the number of conductors extending in the second direction extend beyond the contact points, and/or
contact points are provided as part of the crossing points between first and second conductive tracks, wherein optionally end regions of the number of conductors extending in the second direction extend beyond the contact points.

20. The transparent laminated pane according to claim 16, wherein the first and second conductive tracks are arranged substantially at an angle of 85° to 95°, at an angle of 30° to 50° or at an angle of 55° to 65° to each other and at least some of the crossing points are conductively coupled to each other.

21. The transparent laminated pane according to claim 16, wherein the number of conductors extending in the second direction electrically connect the two other regions to each other.

22. The transparent laminated pane according to claim 16,
wherein the insulating layer extends to first and/or second conductive tracks, which are arranged in the second region and/or the third region, or
wherein first and/or second conductive tracks adjacent to the subregion, which are arranged in the second region and/or the third region are substantially free of a material of the insulating layer.

23. The transparent laminated pane according to claim 16, wherein the subregion comprises a width substantially limited by the second region and/or the third region.

24. The transparent laminated pane according to claim 16, wherein two of the at least three regions are coupled to one another via an optoelectronic component.

25. The transparent laminated pane according to claim 16,
wherein the insulating layer is strip-shaped along the second conductive tracks, or
wherein the insulating layer is ring-shaped on crossing points between the first conductive tracks and the number of conductors extending in the second direction.

26. The transparent laminated pane according to claim 16, wherein the number of conductors extending in the second direction on the insulating layer is laterally offset with respect to the second conductive tracks of the grid structure connected to the number of conductors.

27. A method for manufacturing a plurality of conductive tracks on a transparent target substrate, the method comprising:
providing the target substrate with a grid structure arranged thereon comprising a plurality of conductive tracks extending in a first direction and a plurality of conductive tracks extending in a second direction crossing the conductive tracks extending in the first direction, wherein the grid structure comprises at least three spatially separated regions, and wherein at least one of the three regions comprises a subregion comprising a subset of the plurality of conductive tracks extending in the first direction and no conductive tracks extending in the second direction;
forming an insulating layer at least partially on the subset of the plurality of conductive tracks extending in the first direction in the subregion; and
applying a number of conductors extending in the second direction to the insulating layer and contacting the conductors with conductive tracks of one of a first region or a second region.

28. The method according to claim 27, wherein forming the insulating layer comprises:
forming a strip-shaped insulating layer on the subregion along the number of conductors extending in the second direction or along the second conductive tracks, or
forming a set of elements from the insulating layer on crossing points between the first conductive tracks and the number of conductors extending in the second direction.

29. The method according to claims 27, wherein a plurality of conductors extending in the second direction comprise:
a cross structure arranged in a contact region comprising several of the number of conductors extending in the second direction and sections arranged perpendicularly thereto, or
a grid contact structure arranged in the contact region, wherein a grid length of which corresponds to a grid length of the grid structure, or
circular, elliptical, star-shaped or square contact points whose positions correspond to crossing points of first and second conductive tracks of the respective region.

30. The method according to claim 27, wherein a plurality of conductors extending in the second direction comprises:
a cross structure arranged in a contact region comprising several of the number of conductors extending in the second direction and sections arranged perpendicularly thereto, or
a grid contact structure arranged in the contact region, wherein a grid length of which corresponds to a grid length of the grid structure, or
circular, elliptical, star-shaped or square contact points whose positions correspond to crossing points of first and second conductive tracks of the respective region.
